(19) United States
(12) Patent Application Publication
(10) Pub. No.: US 2026/0173670 A1
(43) Pub. Date: Jun. 18, 2026

(54) DISPLAY DEVICE AND ELECTRONIC DEVICE INCLUDING THE SAME

(71) Applicant: Samsung Display Co., LTD., Yongin-si (KR)

(72) Inventors: Eok Su KIM, Yongin-si (KR); Tae Sang KIM, Yongin-si (KR); Joon Seok PARK, Yongin-si (KR); Sun Hee LEE, Yongin-si (KR)

(73) Assignee: Samsung Display Co., LTD., Yongin-si (KR)

(21) Appl. No.: 19/270,834

(22) Filed: Jul. 16, 2025

(30) Foreign Application Priority Data
Dec. 17, 2024 (KR) 10-2024-0188926

(51) Int. Cl. H10K 59/124

(52) U.S. Cl. CPC H10K 59/124

(57) ABSTRACT

A display device includes a first buffer layer disposed on a substrate, a first active layer disposed on the first buffer layer, a first interlayer insulating layer disposed on the first buffer layer and the first active layer, a first interlayer conductive layer disposed on the first interlayer insulating layer, a second interlayer insulating layer disposed on the first interlayer conductive layer, a second buffer layer disposed on the second interlayer insulating layer, and a second active layer disposed on the second buffer layer. The first interlayer insulating layer includes a first contact hole exposing the first active layer in a thickness direction, and in a plan view, the first contact hole does not overlap the second active layer.

### CROSS-REFERENCE TO RELATED APPLICATION(S)

This application claims priority to and the benefits of Korean Patent Application No. 10-2024-0188926 under 35 USC § 119, filed on Dec. 17, 2024, in the Korean Intellectual Property Office (KIPO), the entire contents of which are incorporated herein by reference.

### BACKGROUND

### 1. Technical Field

The disclosure relates to a display device and an electronic device including the same.

### 2. Description of the Related Art

Recently, as interest in information display has increased, research and development on a display device have been continuously carried out.

With the advancement of information technology, the importance of the display device as a medium connecting users and information has become more prominent. Accordingly, the use of the display device such as a Liquid Crystal Display device and an Organic Light Emitting Display device has been increasing.

The display device includes a data driver for driving data lines, a gate driver for driving scan lines, and pixels connected between the scan lines and the data lines.

The gate driver may include multiple stages dependently connected to each other, and each of the stages may be connected to a corresponding scan line to supply a gate signal. In this case, reliability of driving of a component (e.g., a transistor) constituting the gate driver may be deteriorated by a step of multiple layers constituting the gate driver.

The above description is provided solely to aid in understanding the background technology related to the technical concepts of the disclosure and, therefore, should not be construed as prior art known to those skilled in the technical field of the disclosure.

### SUMMARY

The embodiments of the disclosure provide a display device driven with improved reliability and an electronic device including the same.

A display device according to an embodiment of the disclosure may include a first buffer layer disposed on a substrate, a first active layer disposed on the first buffer layer, a first interlayer insulating layer disposed on the first buffer layer and the first active layer, a first interlayer conductive layer disposed on the first interlayer insulating layer, a second interlayer insulating layer disposed on the first interlayer conductive layer, a second buffer layer disposed on the second interlayer insulating layer, and a second active layer disposed on the second buffer layer. The first interlayer insulating layer may include a first contact hole exposing the first active layer in a thickness direction, and in a plan view, the first contact hole may not overlap the second active layer.

In the plan view, the second active layer may include active patterns arranged with a gap in a first direction and extending in a second direction intersecting the first direction.

A diameter of the first contact hole in the plan view may be smaller than the gap between the active patterns of the second active layer.

The display device may further include a second gate layer disposed on the second active layer and extending in the first direction.

The first contact hole may not overlap the second gate layer in the plan view.

The first contact hole may be arranged adjacent to the second active layer in the first direction and adjacent to the second gate layer in the second direction.

The display device may further include a first gate layer disposed between the first interlayer insulating layer and the first active layer. The first contact hole may expose the first gate layer in the thickness direction.

The display device may further include a third interlayer insulating layer disposed on the second active layer, the second gate layer, and the second buffer layer. The third interlayer insulating layer may include a third contact hole overlapping the second active layer in the plan view.

In the plan view, the third contact hole may not overlap the first contact hole.

The third contact hole may expose the second active layer in the thickness direction.

The display device may further include a second interlayer conductive layer disposed on the third interlayer insulating layer. The second interlayer conductive layer may contact the second active layer through the third contact hole.

In the plan view, the second interlayer conductive layer may overlap the first contact hole.

The display device may further include a display area including one or more pixels, a non-display area located adjacent to the display area, and a gate driver that transmits a gate signal to the one or more pixel and is disposed in the non-display area.

The gate driver may include a buffer transistor including the second active layer, the second gate layer, and the second interlayer conductive layer in the non-display area.

The second interlayer conductive layer overlapping the third contact hole in the plan view may be included in a channel region of the buffer transistor.

An electronic device according to an embodiment of the disclosure may include a processor, and a display device including pixels, the display device displaying an image under control of the processor. The display device may further include a first buffer layer disposed on a substrate, a first active layer disposed on the first buffer layer, a first interlayer insulating layer disposed on the first buffer layer and the first active layer, a first interlayer conductive layer disposed on the first interlayer insulating layer, a second interlayer insulating layer disposed on the first interlayer conductive layer, a second buffer layer disposed on the second interlayer insulating layer, and a second active layer disposed on the second buffer layer. The first interlayer insulating layer may include a first contact hole exposing the first active layer in a thickness direction, and in a plan view, the first contact hole may not overlap the second active layer.

In the plan view, the second active layer may include active patterns arranged with an interval in a first direction and extending in a second direction intersecting the first direction, and a diameter of the first contact hole in the plan view may be smaller than the interval between the active patterns of the second active layer.

The electronic device may further include a second gate layer disposed on the second active layer and extending in the first direction. The first contact hole may not overlap the second gate layer in the plan view.

The electronic device may further include a third interlayer insulating layer disposed on the second active layer, the second gate layer, and the second buffer layer. The third interlayer insulating layer may include a third contact hole overlapping the second active layer in the plan view.

In the plan view, the third contact hole may not overlap the first contact hole.

According to the embodiments of the disclosure, the display device and the electronic device including the same may be driven with improved reliability.

Effects according to the embodiments are not limited by what is explained or illustrated above, and more various effects are included in the specification.

### BRIEF DESCRIPTION OF THE DRAWINGS

FIG. 1 is a schematic plan view illustrating a display device according to an

embodiment.

FIG. 2 is a schematic block diagram illustrating components of the display device of FIG. 1.

FIG. 3 is a schematic diagram illustrating an embodiment of a stage included in a gate driver.

FIG. 4 is a schematic diagram illustrating a gate driver according to an embodiment of the disclosure.

FIG. 5 is a schematic block diagram illustrating an embodiment of one of the sub-pixels of FIG. 1.

FIG. 6 is a schematic cross-sectional view illustrating an embodiment of the display panel of FIG. 1.

FIG. 7 is a schematic cross-sectional view illustrating a partially stacked structure of a display device according to a comparative example of the disclosure.

FIG. 8 is a plan view schematically illustrating a layout of a buffer transistor according to an embodiment of the disclosure.

FIGS. 9 to 13 are plan views illustrating a first area of FIG. 8 to show a stepwise stacked structure of a display device.

FIG. 14 is a schematic cross-sectional view illustrating a stacked structure of a first area according to an AB line of FIG. 13.

FIG. 15 is a schematic block diagram illustrating an electronic device according to embodiments of the disclosure.

FIG. 16 is a schematic diagram illustrating an embodiment in which the electronic device of FIG. 15 is implemented as a smartphone.

FIG. 17 is a schematic diagram illustrating an embodiment in which the electronic device of FIG. 15 is implemented as a tablet PC.

### DETAILED DESCRIPTION OF THE EMBODIMENTS

Hereinafter, embodiments of the disclosure will be described in detail with reference to the accompanying drawings. It should be noted that in the following description, only the parts necessary to understand the operation of the disclosure are described, and descriptions of other parts will be omitted so as not to obscure the gist of the disclosure. The disclosure is not limited to the embodiments described herein, and may be embodied in other forms. However, the embodiments described herein are provided to explain the technical idea of the disclosure in detail to a person skilled in the art to which the disclosure belongs.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The terminology used herein is for the purpose of describing particular embodiments and is not intended to limit the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Here, although terms such as first, second, and the like may be used to describe various components, these components are not limited to these terms. These terms are used to distinguish one component from another. Accordingly, a first component may refer to a second component without departing from what is disclosed herein.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

Various embodiments are described with reference to the figures schematizing embodiments. Accordingly, it will be appreciated that the shapes may vary depending on, for example, tolerances and/or manufacturing techniques. Accordingly, the embodiments disclosed herein are not to be construed as limited to the particular shapes shown, but are to be interpreted as including, for example, changes in shapes that occur as a result of fabrication. As such, the shapes shown in the drawings may not show actual shapes of areas of the apparatus, and the embodiments are not limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

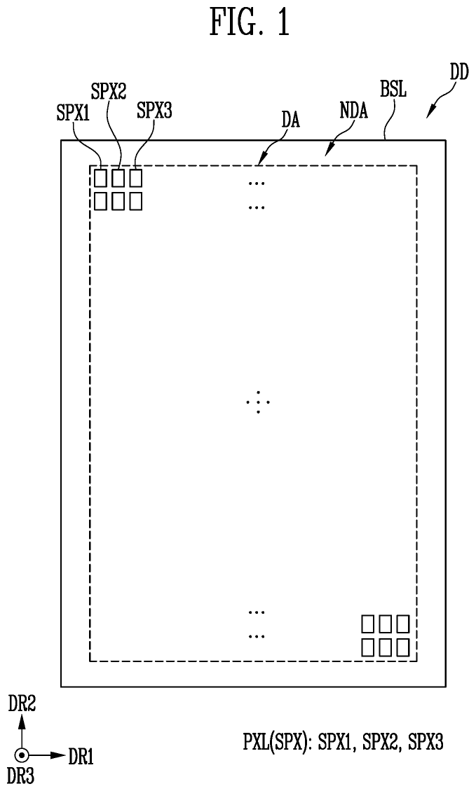

FIG. 1 is a schematic plan view illustrating a display device according to an embodiment.

Referring to FIG. 1, a display device DD may include a base layer BSL and a pixel PXL disposed on the base layer BSL.

The display device DD (or the base layer BSL) may include a display area DA and a non-display area NDA. The non-display area NDA may be an area outside the display area DA. The non-display area NDA may surround at least a part of the display area DA in a plan view.

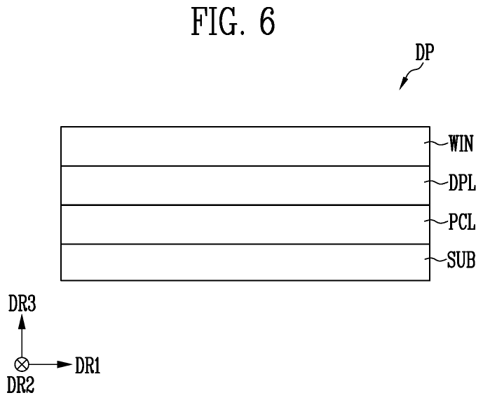

The base layer BSL may form a base surface of the display device DD. The base layer BSL may be a substrate SUB (see FIG. 6) or a film with rigidity or flexibility, as described below. For example, the base layer BSL may be a rigid substrate made of glass or tempered glass, a flexible substrate (or thin film) made of a plastic or a metal, or at least one insulating layer. The material and/or physical properties of the base layer BSL are not particularly limited. In an embodiment, the base layer BSL may be substantially transparent. Here, substantially transparent may mean that light may be transmitted with a certain transmittance level. In other embodiments, the base layer BSL may be translucent or opaque. The base layer BSL may include a reflective material according to an embodiment.

The display area DA may be an area in which the pixel PXL is disposed. The non-display area NDA may be an area in which the pixel PXL is not disposed. A driving circuit, wirings, and pads connected to the pixel PXL in the display area DA may be disposed in the non-display area NDA.

According to an embodiment, the pixel PXL (or sub-pixels SPX) may be arranged according to a stripe or a PENTILE™ arrangement structure or the like, but the disclosure is not limited thereto, and various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may constitute one pixel unit capable of emitting light of various colors.

For example, each of the first sub-pixel SPX1, the second sub-pixel SPX2, and the third sub-pixel SPX3 may emit light of one color. For example, the first sub-pixel SPX1 may be a red pixel that emits light in red (e.g., a first color), the second sub-pixel SPX2 may be a green pixel that emits light in green (e.g., a second color), and the third sub-pixel SPX3 may be a blue pixel that emits light in blue (e.g., a third color). According to an embodiment, the number of the second sub-pixels SPX2 may be greater than the number of the first sub-pixel SPX1 and the number of the third sub-pixels SPX3. However, the color, the type, and/or the number of each of the first sub-pixel SPX1, the second sub-pixel SPX2, and the third sub-pixel SPX3 constituting the pixel unit are not limited to specific examples.

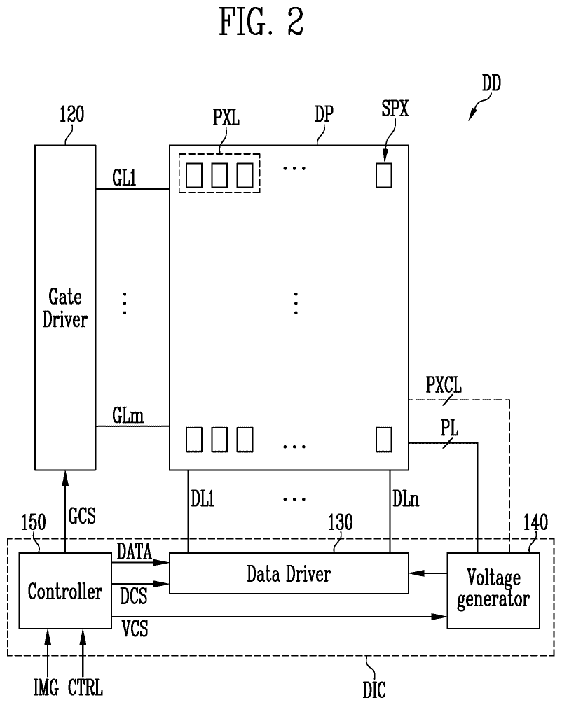

FIG. 2 is a schematic block diagram illustrating components of the display device of FIG. 1.

Referring to FIG. 2, a display device DD may include a display panel DP, a gate driver 120, a data driver 130, a voltage generator 140, and a controller 150.

The display panel DP may include sub-pixels SPX. The sub-pixels SPX may be connected to the gate driver 120 through first to m-th gate lines GL1 to GLm. The sub-pixels SPX may be connected to the data driver 130 through first to n-th data lines DL1 to DLn.

The sub-pixels SPX may generate light of two or more colors. For example, each of the sub-pixels SPX may generate light such as red, green, blue, cyan, magenta, yellow, or the like.

Two or more sub-pixels of the sub-pixels SPX may constitute a pixel PXL. For example, the pixel PXL may include three sub-pixels as shown in FIG. 1. As such, the pixel PXL may emit light of various colors and various luminances according to a combination of light emitted from sub-pixels included in the pixel PXL.

The gate driver 120 may be connected to the sub-pixels SPX arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be located on a side of the display panel DP. However, embodiments are not limited thereto. For example, the gate driver 120 may be divided into two or more drivers that are physically and/or logically divided, and such drivers may be disposed on a side of the display panel DP and the another of the display panel DP opposite to the side. As such, the gate driver 120 may be disposed around the display panel DP in various forms according to embodiments.

The data driver 130 may be connected to the sub-pixels SPX arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that a gate signal is applied to each of the first to m-th gate lines GL1 to GLm, data signals corresponding to the image data DATA may be applied to the data lines DL1 to DLn. Accordingly, the sub-pixels SPX may generate light corresponding to the data signals, and the display panel DP may display an image.

In embodiments, gate driver 120 and data driver 130 may include complementary metal-oxide semiconductor (CMOS) circuit elements.

The voltage generator 140 may operate in response to a voltage control signal VCS from the controller 150. The voltage generator 140 may be configured to generate multiple voltages and provide the generated voltages to components of the display device DD, such as the gate driver 120, the data driver 130, and the controller 150. The voltage generator 140 may generate the voltages by receiving an input voltage from outside the display device DD and regulating the received voltage.

The voltage generator 140 may generate a first power voltage and a second power voltage. The first and second power voltages may be provided to the sub-pixels SPX through power lines PL. In other embodiments, at least one of the first and second power voltages may be provided from outside the display device DD.

The voltage generator 140 may provide various voltages and/or signals. For example, the voltage generator 140 may provide one or more initialization voltages to the sub-pixels SPX. For example, in a sensing operation for sensing electrical characteristics of transistors and/or light-emitting elements of the sub-pixels SPX, a reference voltage may be applied to the first to n-th data lines DL1 to DLn, and the voltage generator 140 may generate and transmit the reference voltage to the data driver 130. For example, in a display operation for displaying an image on the display panel DP, pixel control signals may be commonly applied to the sub-pixels SPX, and the voltage generator 140 may generate the pixel control signals. In embodiments, voltage generator 140 may provide the pixel control signals to the sub-pixels SPX through pixel control lines PXCL. Although the pixel control lines PXCL are shown in FIG. 2 as being connected between the voltage generator 140 and the display panel DP, embodiments are not limited thereto. For example, the pixel control lines PXCL may be connected between the gate driver 120 and the display panel DP, and the pixel control signals may be transmitted from the voltage generator 140 to the pixel control lines PXCL through the gate driver 120.

The controller 150 may control various operations of the display device DD. The controller 150 may receive input image data IMG and a control signal CTRL corresponding the input image data IMG from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP and output the image data DATA. In embodiments, the controller 150 may output the image data DATA by arranging the input image data IMG to fit the sub-pixels SPX in rows.

Two or more components of the data driver 130, the voltage generator 140, and the controller 150 may be mounted in one integrated circuit. As shown in FIG. 2, the data driver 130, the voltage generator 140, and the controller 150 may be included in a driver integrated circuit (DIC), and the data driver 130, the voltage generator 140, and the controller 150 may be functionally distinct components in the driver integrated circuit (DIC). In other embodiments, at least one of the data driver 130, the voltage generator 140, and the controller 150 may be provided as a component separate from the driver integrated circuit (DIC).

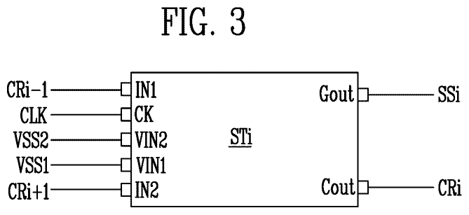

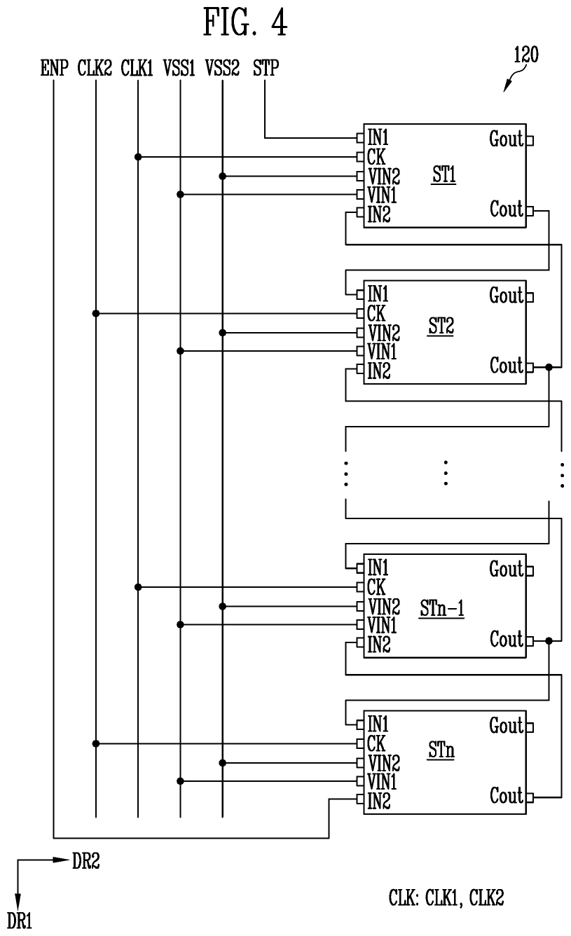

FIG. 3 is a schematic diagram illustrating an embodiment of a stage included in a gate driver. FIG. 3 schematically illustrates a stage positioned on an i-th horizontal line. FIG. 4 is a schematic diagram illustrating a gate driver according to an embodiment of the disclosure.

Referring to FIG. 3, a stage STi according to an embodiment of the disclosure may include a first input terminal IN1, a second input terminal IN2, a first power input terminal VIN1, a second power input terminal VIN2, a clock input terminal CK, a first output terminal Gout, and a second output terminal Cout.

Referring to FIGS. 3 and 4, the first input terminal IN1 may receive a carry signal CRi-1 (or a start signal STP) of a previous stage. In case that the carry signal CRi−1 of the previous stage is provided to the first input terminal IN1, the stage STi may output a gate signal SSi through the first output terminal Gout, and the gate signal SSi may be output to the i-th gate line GLi. In case that the carry signal CRi−1 of the previous stage is provided to the first input terminal IN1, the stage STi may output the carry signal CRi through the second output terminal Cout.

The second input terminal IN2 may receive a carry signal CRi+1 (or an end signal ENP) of a next stage. In case that the carry signal CRi+1 of the next-stage is provided to the second input terminal IN2, the stage STi may stop outputting the gate signal SSi and the carry signal CRi.

The clock input terminal CK may receive a clock signal CLK. For example, the clock input terminal CK included in an odd-numbered (or even-numbered) stage may be supplied with a first clock signal CLK1, and the clock input terminal CK included in an even-numbered (or odd-numbered) stages may be supplied with a second clock signal CLK2. The first clock signal CLK1 and the second clock signal CLK2 may be alternately provided to the stages for each horizontal line.

The first power input terminal VIN1 may receive a voltage of a first power VSS1. The second power input terminal VIN2 may receive a voltage of a second power VSS2. The first power VSS1 and the second power VSS2 may have a gate-off voltage. For example, the transistor to which the voltage of the first power VSS1 or the voltage of the second power VSS2 is supplied to a gate electrode may be set to a turn-off state.

The first output terminal Gout may output the gate signal SSi. The second output terminal Cout may output the carry signal CRi. The carry signal CRi may be supplied to the previous stage and the next stage.

Referring to FIG. 4, a gate driver 120 according to an embodiment of the disclosure may include stages ST1, ST2, . . . , STn-1, and STn.

Each of the stages ST1 to STn may be connected to a scan line among the SL1 to SLn, and may be arranged in a first direction DR1. The first stage ST1 may be positioned in a top area of the gate driver 120 (or above the display panel DP), and the n-th stage STn may be positioned in a bottom area of the gate driver 120 (or below the display panel DP). In each of the stages ST1 to STn, the first input terminal IN1 may be positioned above the second input terminal IN2.

The first stage ST1 may be a stage that supplies the gate signal corresponding to the start signal STP. The n-th stage STn may be a stage in which the supply of the gate signal is interrupted by the end signal ENP.

Each of the first to n-th stages ST1 to STn may sequentially output the gate signal SSi through the first output terminal Gout, and the second to n-th stages ST2 to STn may be driven by receiving the carry signal CRi output from the second output terminal Cout of the previous stage.

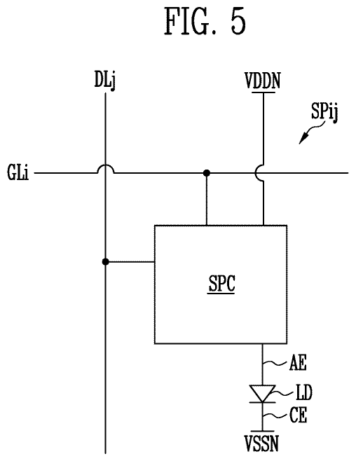

FIG. 5 is a schematic block diagram illustrating an embodiment of one of the sub-pixels of FIG. 1. In FIG. 5, among the sub-pixels SPX of FIG. 1, a sub-pixel SPij arranged in an i-th row (i is an integer greater than or equal to 1 and less than or equal to m) and a j-th column (j is an integer greater or equal to 1 and less than or equivalent to n) is exemplarily shown.

Referring to FIG. 5, the sub-pixel SPij may include a sub-pixel circuit SPC and a light-emitting element LD.

The light-emitting element LD may be connected between a first power voltage node VDDN and a second power voltage node VSSN. The first power voltage node VDDN may be connected to one of the power supply lines PL of FIG. 1 to receive the first power voltage. The second power voltage node VSSN may be connected to another one of the power supply lines PL of FIG. 1 to receive the second power voltage. The first power voltage may have a higher voltage level than the second power voltage.

The light-emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light-emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to the gate signal received through the i-th gate line GLi, the sub-pixel circuit SPC may control the light-emitting element LD to emit light according to a data signal received through the j-th data line DLj. In embodiments, the sub-pixel circuit SPC may be further connected to the pixel control lines PXCL of FIG. 2, and the sub-pixel circuit SPC may further control the light-emitting element LD in response to pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon, a polycrystalline silicon semiconductor, an oxide semiconductor, or the like.

FIG. 6 is a schematic cross-sectional view illustrating an embodiment of the display panel of FIG. 1.

Referring to FIG. 6, the display panel DP may include a substrate SUB, and a pixel circuit layer PCL, a display element layer DPL, and a window WIN sequentially stacked on the substrate SUB in a third direction DR3 intersecting first and second directions DR1 and DR2. For convenience of explanation, FIG. 6 schematically describes only the display panel DP, but the disclosure is not limited thereto. For example, the display device DD illustrated in FIG. 1 and the display panel DP of FIG. 6 may be same.

The substrate SUB may be made of an insulating material such as glass or a resin. For example, the substrate SUB may include a glass substrate. In another embodiment, substrate SUB may include a polyimide (PI) substrate. In another embodiment, the substrate SUB may include a silicon wafer substrate formed using a semiconductor process.

In embodiments, the substrate SUB may be made of a flexible material to allow bending or folding, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wirings, or the like.

The circuit elements of the pixel circuit layer PCL may include a sub-pixel circuit SPC (see FIG. 5) of each of the sub-pixels SPX of FIG. 1. The circuit elements of the pixel circuit layer PCL may be provided with transistors and one or more capacitors of the sub-pixel circuit SPC.

The wirings of the pixel circuit layer PCL may include wirings connected to the sub-pixels SPX. The wirings of the pixel circuit layer PCL may include various signal lines and/or voltage lines for driving the display element layer DPL.

The display element layer DPL may be disposed on the pixel circuit layer PCL. The display element layer DPL may include light-emitting elements of the sub-pixels SPX.

The window WIN may be disposed on the display element layer DPL. The window WIN may protect an exposed surface (or an upper surface) of the display panel DP. For example, the window WIN may protect the display panel DP from an external impact. The window WIN may be coupled to the display element layer DPL by an optically transparent adhesive (or adhesive) member. The window WIN may have a multi-layer structure including at least one of a glass substrate, a plastic film, and a plastic substrate. The multi-layer structure may be formed through a continuous process or an adhesive process using an adhesive layer. All or part of the window WIN may be flexible.

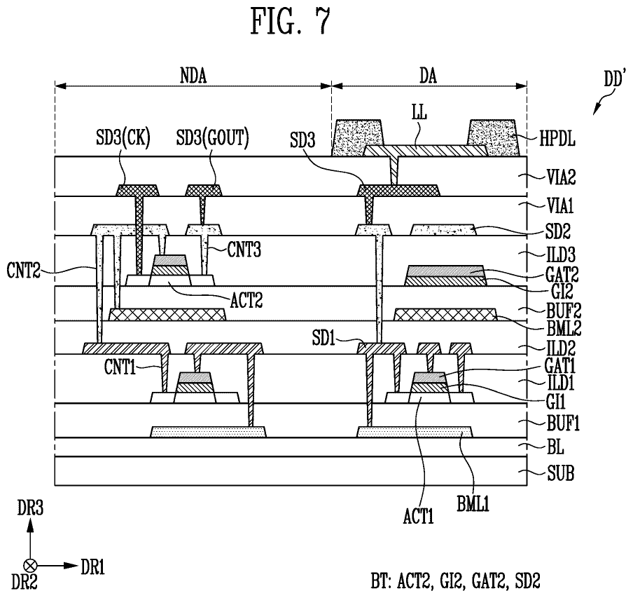

FIG. 7 is a schematic cross-sectional view illustrating a partially stacked structure of a display device according to a comparative example of the disclosure.

Referring to FIG. 7, the display device DD′ may include a substrate SUB. The substrate SUB of FIG. 7 and the substrate SUB in FIG. 6 may be same. Hereinafter, redundant descriptions will be omitted.

The display device DD′ may have a structure in which a barrier layer BL, a first auxiliary electrode layer BML1, a first buffer layer BUF1, a first active layer ACT1, a first gate insulating layer GI1, a first gate layer GAT1, a first interlayer insulating layer ILD1, a first interlayer conductive layer SD1, a second interlayer insulating layer ILD2, a second auxiliary electrode layer BML2, a second buffer layer BUF2, a second active layer ACT2, a second gate insulating layer GI2, a second gate layer GAT2, a third interlayer insulating layer ILD3, a second interlayer conductive layer SD2, a first via layer VIA1, a third interlayer conductive layer SD3, and a second via layer VIA2 are sequentially stacked on the substrate SUB, and at least a part of the structure may have a patterned shape.

According to an embodiment, the first and second active layers ACT1 and ACT2 may include a semiconductor. For example, the first and second active layers ACT1 and ACT2 may include at least one of polysilicon, low temperature polycrystalline silicon (LTPS), amorphous silicon, and oxide semiconductor.

The number and material of conductive layers and insulating layers forming the display device DD′ are not particularly limited to the above-described example, and the number and material of the conductive layers and the insulating layers may be variously changed.

According to an embodiment, the buffer layer BFL, the first gate insulating layer GI1, the second gate insulating layer GI2, and the first to third interlayer insulating layers ILD1 to ILD3 may include an inorganic material. According to an embodiment, the first and second via layers VIA1 to VIA2 may include an organic material. According to an embodiment, the first auxiliary electrode layer BML1, the second auxiliary electrode layer BML2, the first and second gate layers GAT1 and GAT2, and the first to third interlayer conductive layers SD1 to SD3 may include a conductive material.

According to an embodiment, the organic material may include at least one of an acrylic resin, an epoxy resin, a phenol resin, a polyamide resin, a polyimide resin, a polyester resin, a polyphenylenesulfide resin, and benzocyclobutene. However, the disclosure is not limited thereto.

According to an embodiment, the inorganic material may include at least one of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), and silicon oxynitride (SiOₓN_{y}). However, the disclosure is not limited thereto.

According to an embodiment, a light emitting layer LL may be disposed on the second via layer VIA2 in a display area DA of the display device DD′. The light emitting layer LL may be a layer constituting the light-emitting element LD of FIG. 5 described above. Thereafter, a pixel defining layer HPDL (or a pixel defining layer) HPDL surrounding the light emitting layer LL may be disposed.

Above-described electrode layers may be patterned according to one structure to form a pixel circuit. For example, a part of the first active layer ACT1, a part of the first gate layer GAT1, and a part of the first interlayer conductive layer SD1 in the display area DA may form a driving transistor. Accordingly, the first active layer ACT1 may be connected to the light emitting layer LL through the first to third interlayer conductive layers SD1 to SD3 to control light emission of the light-emitting element LD (see FIG. 5). For example, the driving transistor may be a component included in the sub-pixel circuit SPC (see FIG. 5). However, the disclosure is not limited thereto.

According to an embodiment, a part of the second active layer ACT2, a part of the second gate layer GAT2, a part of the second interlayer conductive layer SD2, and a part of the third interlayer conductive layer SD3 in the non-display area NDA may form a buffer transistor BT. The buffer transistor BT may constitute a gate driver 120 (see FIG. 4).

According to an embodiment, a part of the first active layer ACT1, a part of the first gate layer GAT1, a part of the first interlayer conductive layer SD1, and a part of the first auxiliary electrode layer BML1 in the non-display area NDA may form an operation transistor constituting a logic circuit. The operation transistor may constitute a gate driver 120 (see FIG. 4).

The third interlayer conductive layer SD3 in the non-display area NDA may include the clock input terminal CK and the first output terminal Gout described above with reference to FIG. 4. Accordingly, the buffer transistor BT may output the gate signal SSi (see FIG. 4) according to an input signal received from a logic circuit (or the operation transistor). However, the disclosure is not limited thereto.

According to an embodiment, at least some of the layers described above may have a contact hole exposing a layer disposed below. Hereinafter, for convenience of explanation, a portion of the display device DD′ in the non-display area NDA will be described.

According to an embodiment, the first interlayer insulating layer ILD1 may have a first contact hole CNT1 that exposes the first active layer ACT1 disposed below the first interlayer insulating layers ILD1 in a thickness direction (or the third direction DR3). For example, the first interlayer conductive layer SD1 may be connected to the first active layer ACT1 through the first contact hole CNT1.

According to an embodiment, the second interlayer insulating layer ILD2, the second buffer layer BUF2, and the third interlayer insulating layer ILD3 may have a second contact hole CNT2 that exposes the first interlayer conductive layer SD1 disposed below the second interlayer insulating layers ILD2 in the thickness direction. For example, the second interlayer conductive layer SD2 may be connected to the first interlayer conductive layer SD1 through the second contact hole CNT2. Accordingly, the second interlayer conductive layer SD2 may be connected to the first active layer ACT1 via the first interlayer conductive layer SD1.

According to an embodiment, the third interlayer insulating layer ILD3 may have a third contact hole CNT3 exposing the second active layer ACT2. For example, the second interlayer conductive layer SD2 may be connected to the second active layer ACT2 through the third contact hole CNT3.

According to a comparative example, the first contact hole CNT1 and the second active layer ACT2 may overlap each other in the third direction DR3. Accordingly, a thickness of a channel region of the buffer transistor BT overlapping the first contact hole CNT1 in the third direction DR3 may not be uniform. For example, a thickness of the channel region of the buffer transistor BT may not be uniform due to a step difference caused by the first contact hole CNT1 and the first interlayer conductive layer SD1 overlapping the first contact hole CNT1, and a risk of lowering reliability of driving of the buffer transistor BT may occur.

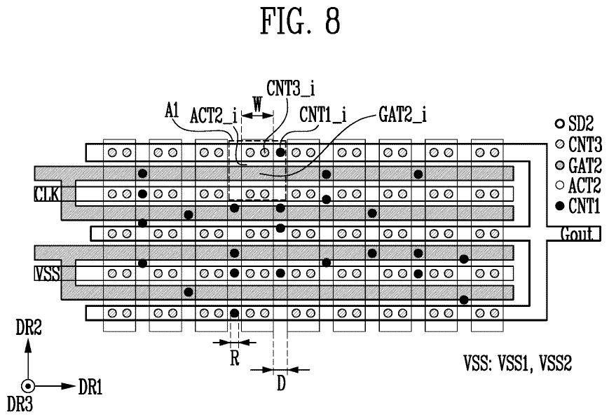

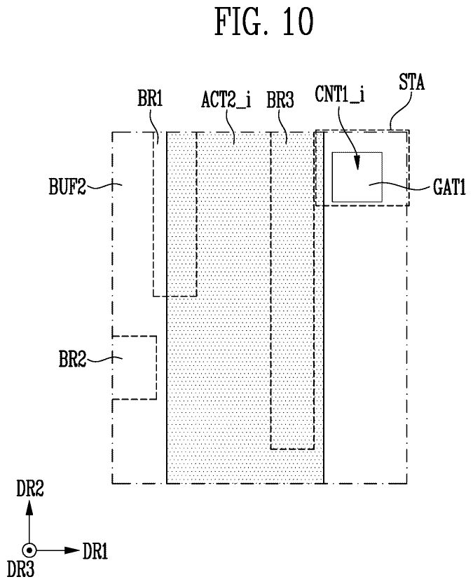

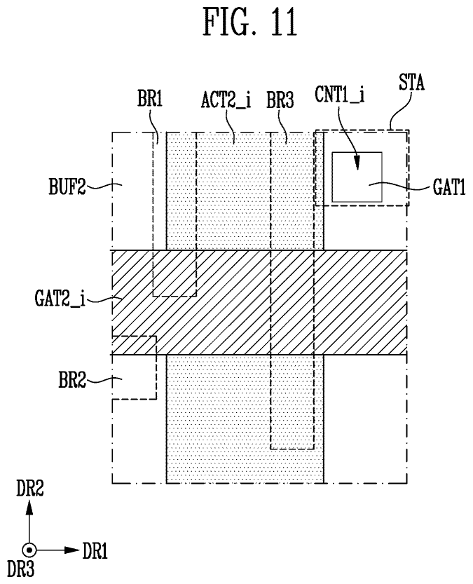

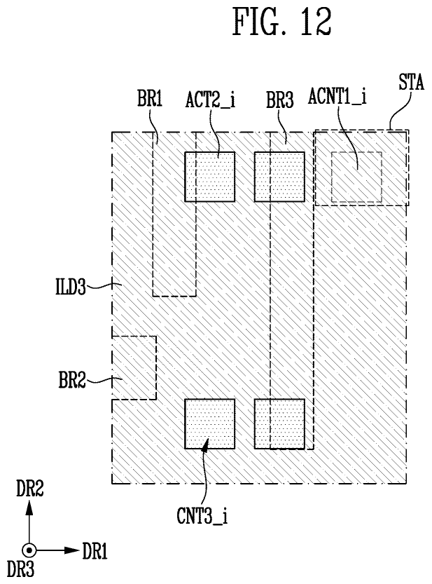

Hereinafter, a stacked structure of a display panel according to an embodiment of the disclosure will be described with reference to FIGS. 8 to 14.

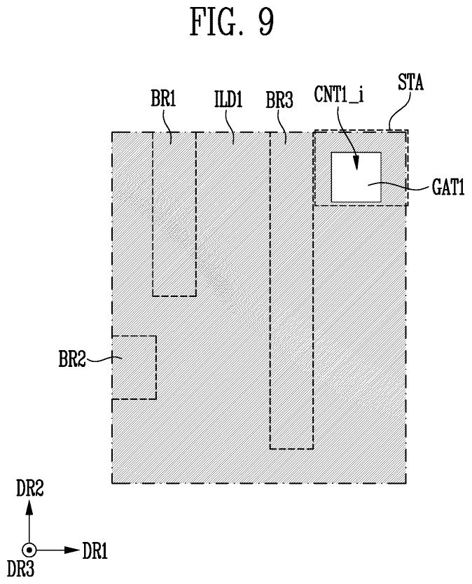

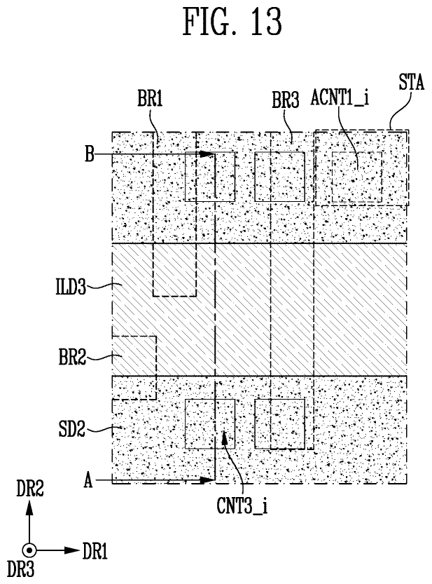

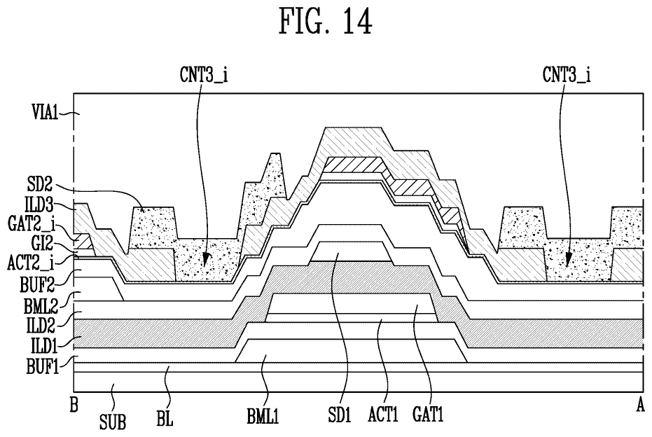

FIG. 8 is a plan view schematically illustrating a layout of a buffer transistor according to an embodiment of the disclosure. FIGS. 9 to 13 are plan views illustrating a first area of FIG. 8 to show a stepwise stacked structure of a display device. FIG. 14 is a schematic cross-sectional view illustrating a stacked structure of a first area according to line AB of FIG. 13.

FIG. 8 schematically illustrates a buffer transistor BT (see FIG. 7), a second interlayer conductive layer SD2, a second gate layer GAT2, and a second active layer ACT2 in the non-display area NDA according to an embodiment of the disclosure. According to an embodiment, the second interlayer conductive layer SD2, the second gate layer GAT2, and the second active layer ACT2 of FIG. 8 may be one of wirings of the gate driver 120 illustrated in FIG. 4.

FIG. 8 schematically illustrates a planar arrangement relationship of a first contact hole CNT1, a third contact hole CNT3, and a second active layer ACT2 according to an embodiment of the disclosure.

Referring to FIG. 8, the second active layer ACT2 may be formed of one or more patterns extending in the second direction DR2 while being spaced apart by a gap (or interval, distance) in the first direction DR1. For example, the second active layer ACT2 may include a 2_i-th active layer ACT2_i disposed in an i-th column of patterns of the second active layer ACT2. For convenience of explanation, the 2_i-th active layer ACT2_i will be described below, but the disclosure is not limited thereto.

A length of the 2_i-th active layer ACT2_i in the first direction DR1 may be defined as a first length W. The gap between patterns of the second active layer ACT2 in the first direction DR1 may be defined as a second length D. According to an embodiment, the first length W may be greater than the second length D. However, the disclosure is not limited thereto. For example, the first length W may be less than the second length D.

The second gate layer GAT2 may extend in the first direction DR1 and may overlap the second active layer ACT2 in the third direction DR3. The second gate layer GAT2 may be composed of two units branched in a direction opposite to the second direction DR2 and extending in the first direction DR1. However, the disclosure is not limited thereto.

At least a portion of the second gate layer GAT2 may extend in the first direction DR1 and may overlap the 2_i-th active layer ACT2_i in the third direction DR3. The second gate layer GAT2 may include a 2_i-th gate layer GAT2_i overlapping the 2_i-th active layer ACT2_i in the third direction DR3.

The second interlayer conductive layer SD2 may extend in the first direction DR1 and may at least partially overlap the second active layer ACT2 in the third direction DR3. The second interlayer conductive layer SD2 may not overlap the second gate layer GAT2 in the third direction DR3. For example, the second interlayer conductive layer SD2 may include patterns that are spaced apart from each other in the second direction DR2 at a gap and extend in the first direction DR1. The second gate layer GAT2 may be disposed between the patterns of the second interlayer conductive layer SD2 and spaced apart from the patterns in the second direction DR2. However, the disclosure is not limited thereto.

In a plan view, the first contact hole CNT1 may not overlap the second active layer ACT2 in the third direction DR3. For example, the first contact hole CNT1 may include a 1_i-th contact hole CNT1_i adjacent to the 2_i-th active layer ACT2_i. The 1_i-th contact hole CNT1_i may not overlap the 2_i-th active layer ACT2_i in the third direction DR3.

In a plan view, the first contact hole CNT1 may overlap one of the second interlayer conductive layer SD2 and the second gate layer GAT2 in the third direction DR3. However, the disclosure is not limited thereto, and according to another embodiment, the first contact hole CNT1 may not overlap any one of the second interlayer conductive layer SD2 and the second gate layer GAT2 in the third direction DR3.

The first contact hole CNT1 may have a diameter equal to a third length R in a plan view. The third length R may be less than the second length D. For example, the gap between the patterns of the second active layer ACT2 may be wider than the diameter of the first contact hole CNT1. Accordingly, the first contact hole CNT1 may be disposed between patterns of the second active layer ACT2 and may not overlap the second active layer in the third direction DR3. As the process progresses, the first contact hole CNT1 may have a diameter greater than intended. In order to prevent the first contact hole CNT1 from overlapping the second active layer ACT2 in a plan view, the second length D may be designed to be greater than the third length R with a preset margin.

The third contact hole CNT3 may overlap the second active layer ACT2 in the third direction DR3. For example, in the first area A1, the third contact hole CNT3 may include a 3_i-th contact hole CNT3_i overlapping the 2_i-th active layer ACT2_i in the third direction DR3.

The third contact hole CNT3 may overlap the second interlayer conductive layer SD2 in the third direction DR3. For example, the third contact hole CNT3 may overlap the second interlayer conductive layer SD2 in the third direction DR3 and may be arranged in the first direction DR1. Two third contact holes CNT3 arranged in the first direction DR1 and overlapping one pattern of the second active layer ACT2 in the third direction DR3 may form one group. However, the disclosure is not limited thereto.

According to an embodiment, multiple signals may be transmitted to the second interlayer conductive layer SD2. For example, a clock signal CLK may be transmitted to at least a portion of the second interlayer conductive layer SD2. An input power VSS may be transmitted to at least a part of the second interlayer conductive layer SD2. The clock signal CLK and the input power VSS may be transferred to one of multiple layers illustrated in FIG. 7 through the first contact hole CNT1 and the third contact hole CNT3.

The second interlayer conductive layer SD2 may include a first output terminal Gout. For example, an end of the second interlayer conductive layer SD2 in the first direction DR1 may include the first output terminal Gout, and the first output terminal GOUT may output a gate signal SSi (see FIG. 3).

The first area A1 may include a 2_i-th active layer ACT2_i and a second interlayer conductive layer SD2 and a second gate layer GAT2 overlapping the 2_i-th active layers ACT2_i in the third direction DR3. The first area A1 may include a 1_i-th contact hole CNT1_i and a 3_i-th contact hole CNT3_i. Hereinafter, for convenience of explanation, the first area A1 will be described, but the disclosure is not limited thereto. For example, other areas may have a same structure as the first area A1.

Referring to FIGS. 8 and 9, the first interlayer insulating layer ILD1 may be disposed in the first area A1. The first interlayer insulating layer ILD1 may include a first pattern BR1, a second pattern BR2, a third pattern BR3, a first contact hole area STA, and a 1_i-th contact hole CNT1_i.

The first pattern BR1, the second pattern BR2, and the third pattern BR3 may have an area and may be an area having a preset step in the third direction DR3 (or a direction opposite to the third direction DR3). For example, the first pattern BR1 may correspond to at least a part of an area where the first active layer ACT1, the first gate insulating layer GI1, and the first gate layer GAT1 overlap in the third direction DR3. However, the disclosure is not limited thereto.

According to an embodiment, in a plan view, the first pattern BR1 and the third pattern BR3 may have a rectangular shape having a long side in the second direction DR2 and a short side in the first direction DR1 on the first interlayer insulating layer ILD1. However, the disclosure is not limited thereto.

The first contact hole area STA may be an area including the first gate layer GAT1 and the 1_i-th contact hole CNT1_i. For example, the first contact hole area STA may include the 1_i-th contact hole CNT1_i exposing the first gate layer GAT1 disposed below the first interlayer insulating layer ILD1 in the third direction DR3.

According to an embodiment, the first contact hole area STA may be formed in multiple stacked structures protruding in the third direction DR3. For example, the 1_i-th contact hole CNT1_i may be an opening recessed in a direction opposite to the third direction DR3 in the first contact hole area STA having the stacked structures.

The 1_i-th contact hole CNT1_i may have a rectangular shape in a plan view. However, the disclosure is not limited thereto. For example, the 1_i-th contact hole CNT1_i may have various planar shapes such as a circle, an ellipse, a triangle, and a pentagonal shape.

Referring to FIGS. 7 to 10, the second buffer layer BUF2 and the 2_i-th active layer ACT2_i may be disposed on the first interlayer insulating layer ILD1.

The 2_i-th active layer ACT2_i may overlap the first contact hole area STA, a portion of the first pattern BR1, and the third pattern BR3 in the third direction DR3. The second buffer layer BUF2 may overlap a remaining portion of the first pattern BR1 and the second pattern BR2 in the third direction DR3. The 2_i-th active layer ACT2_i may be disposed on the second buffer layer BUF2.

In a plan view, the 1_i-th contact hole CNT1_i may not overlap the 2_i-th active layer ACT2_i in the third direction DR3. For example, the 2_i-th active layer ACT2_i may be formed adjacent to the 1_i-th contact hole CNT1_i in the first direction DR1, but may not overlap the 1_i-th contact hole CNT1_i in the third direction DR3. The 1_i-th contact hole CNT1_i may expose the first gate layer GAT1 in the third direction DR3.

As described above with reference to FIG. 7, according to a comparative example, the first contact hole CNT1 may overlap the second active layer ACT2 in the non-display area NDA (see FIG. 7), and there may be a risk that reliability of driving of the buffer transistor BT (see FIG. 7) is degraded. On the other hand, according to an embodiment of the disclosure, the 1_i-th contact hole CNT1_i may not overlap the 2_i-th active layer ACT2_i in the third direction DR3, and the thickness of the channel region of the buffer transistor BT overlapping the 2_i-th active layer ACT2_i may be uniform. Accordingly, the reliability of driving of the display device DD (see FIG. 2) according to an embodiment of the disclosure may be improved.

Referring to FIGS. 7 to 11, the 2_i-th gate layer GAT2_i may be disposed on the second buffer layer BUF2 and the 2_i-th active layer ACT2_i. The 2_i-th gate layer GAT2_i may be formed on the second buffer layer BUF2 and the 2_i-th active layer ACT2_i and may extend in the first direction DR1.

In a plan view, the 2_i-th gate layer GAT2_i may not overlap the 1_i-th contact hole CNT1_i in the third direction DR3. Accordingly, the 1_i-th contact hole CNT1_i may expose the first gate layer GAT1 in the third direction DR3.

Referring to FIGS. 7 to 12, the third interlayer insulating layer ILD3 may be disposed on the layers described above. For example, the third interlayer insulating layer ILD3 may be disposed on the 2_i-th gate layer GAT2_i, the 2_i-th active layer ACT2_i, the second buffer layer BUF2, and the 1_i-th contact hole CNT1_i.

The third interlayer insulating layer ILD3 may include one or more 3_i-th contact holes CNT3_i exposing a layer disposed below the third interlayer insulating layer ILD3. For example, the 3_i-th contact holes CNT3_i may expose the 2_i-th active layer ACT2_i disposed below the third interlayer insulating layer ILD3 in the third direction DR3. The third interlayer insulating layer ILD3 may cover the 1_i-th contact hole CNT1_i. The first gate layer GAT1 may not be exposed in the third direction DR3.

A 1_i-th contact hole area ACNT1_i may be an area overlapping the 1_i-th contact holes CNT1_i in the third direction DR3. For example, the 1_i-th contact hole area ACNT1_i may be an area corresponding to the 1_i-th contact hole CNT1_i covered by the third interlayer insulating layer ILD3. Accordingly, the 1_i-th contact hole area ACNT1_i may not overlap the third contact holes CNT3 in a plan view.

Referring to FIGS. 7 to 13, the second interlayer conductive layer SD2 may be disposed on the third interlayer insulating layer ILD3 and the 3_i-th contact hole CNT3_i. For example, the second interlayer conductive layer SD2 extending in the first direction DR1 may overlap the 3_i-th contact hole CNT3_i in the third direction DR3 and be disposed on the third interlayer insulating layer ILD3 and the 3_i-th touch hole CNT3_i. Accordingly, the 2_i-th active layer ACT2_i that has been exposed in the third direction DR3 through the 3_i-th contact hole CNT3_i may no longer be exposed.

FIG. 14 shows a stack structure according to line AB of the first area A1. The substrate SUB, the barrier layer BL, the first auxiliary electrode layer BML1, the first buffer layer BUF1, the first active layer ACT1, the first gate layer GAT1, the first interlayer insulating layer ILD1, the first interlayer conductive layer SD1, the second interlayer insulating layer ILD2, the second auxiliary electrode layer BML2, the second buffer layer BUF2, the second gate insulating layer GI2, the third interlayer insulating layer IL3, the second interlayer conductive layer SD2, and the first via layer VIA1 in FIG. 14 may be same as the substrate SUB, the barrier layer BL, the first auxiliary electrode layer BML1, the first buffer layer BUF1, the first active layer ACT1, the first gate layer GAT1, the first interlayer insulating layer ILD1, the first interlayer conductive layer SD1, the second interlayer insulating layer ILD2, the second auxiliary electrode layer BML2, the second buffer layer BUF2, the second gate insulating layer GI2, the third interlayer insulating layer IL3, the second interlayer conductive layer SD2, and the first via layer VIA1 in FIG. 7. Hereinafter, redundant descriptions will be omitted.

Referring to FIGS. 7 to 14, the 2_i-th active layer ACT2_i may be disposed on the second buffer layer BUF2. For example, the 2_i-th active layer ACT2_i may be disposed on the second buffer layer BUF2 along the second direction DR2. The 2_i-th active layer ACT2_i of FIG. 14 and the 2_i-th activity layer ACT2_i of FIG. 8 may be same. For example, the 2_i-th active layer ACT2_i of FIG. 14 may be a pattern disposed in the i-th column of the patterns of the second active layer ACT 2 of FIG. 8.

The second gate insulating layer GI2 may be disposed on the 2_i-th active layer ACT2_i. The second gate insulating layer GI2 may not overlap the 3_i-th contact hole CNT3_i in a plan view.

The 2_i-th gate layer GAT2_i may be disposed on the second interlayer insulating layer GI2. The 2_i-th gate layer GAT2_i may not overlap the 3_i-th contact hole CNT3_i in a plan view.

The second interlayer conductive layer SD2 may be disposed on the 2_i-th active layer ACT2_i and the third interlayer insulating layer ILD3. The second interlayer conductive layer SD2 may contact the 2_i-th active layer ACT2_i through the 3_i-th contact hole CNT3_i.

Referring to FIGS. 7 to 14, the second active layer ACT2 (or the 2_i-th active layer ACT2_i ) may not overlap the first contact hole CNT1 (or the 1_i-th contact hole CNT1_i ) in a plan view. The third contact hole CNT3 (or the 3_i-th contact hole CNT3_i ) may not overlap the first contact hole CNT1 (or the 1_i-th contact holeCNT1_i ) in a plan view.

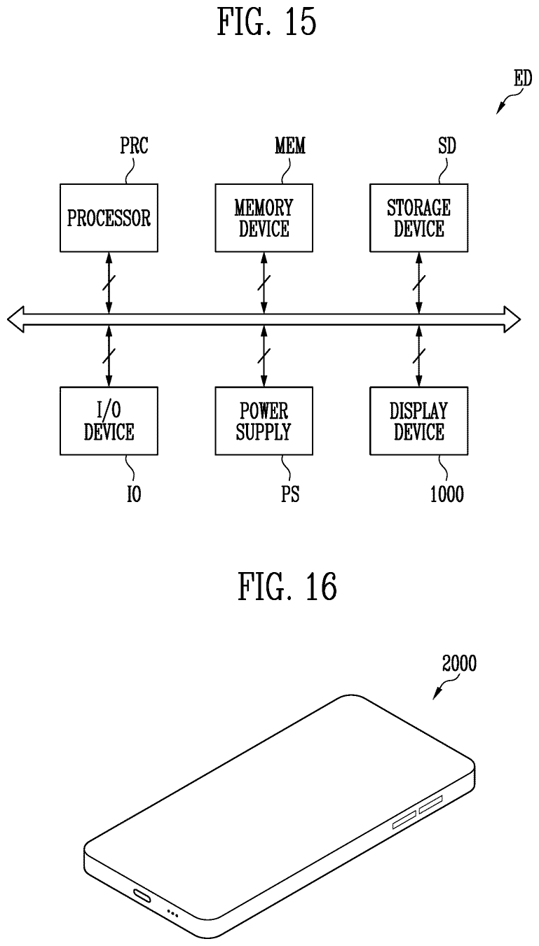

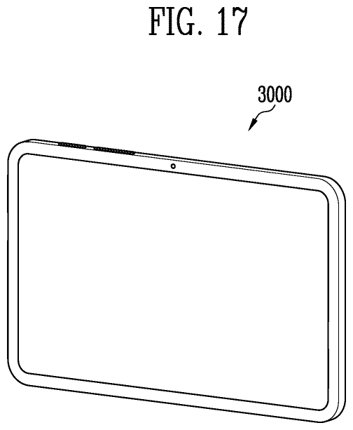

FIG. 15 is a schematic block diagram illustrating an electronic device according to embodiments of the disclosure. FIG. 16 is a schematic diagram illustrating an embodiment in which the electronic device of FIG. 15 is implemented as a smartphone. FIG. 17 is a schematic diagram illustrating an embodiment in which the electronic device of FIG. 15 is implemented as a tablet PC.

Referring to FIG. 15, an electronic device ED may include a processor PRC, a memory device MEM, a storage device SD, an input/output device (I/O device) IO, a power supply PS, and a display device 1000. The display device 1000 may be the display device DD of FIG. 1. The electronic device ED may further include ports that can communicate with a video card, a sound card, a memory card, a USB device, or the like, or with other systems.

The electronic device ED may be implemented as a mobile phone, a video phone, a smart pad, a smart watch, a vehicle navigation device, a computer monitor, a notebook computer, a head mounted display device, or the like.

The processor PRC may perform calculations or tasks. According to an embodiment, the processor PRC may be a microprocessor, a central processing unit, an application processor, or the like. The processor PRC may be connected to other components via an address bus, a control bus, a data bus, and the like. According to an embodiment, the processor PRC may be connected to an extension bus, such as a Peripheral Component Interconnect (PCI) bus.

The memory device MEM may store data for the operation of the electronic device ED. For example, the memory device MEM may include a non-volatile memory device such as an Erasable Programmable Read-Only Memory (EPROM) device, an Electrically Erasable Programmable Read-only Memory (EEPROM) device, a flash memory device, a Phase Change Random Access Memory (PRAM) device, a Resistance Random Access memory (RRAM) device, an Nano Floating Gate Memory (NFGM) device, a Polymer Random Access Memory (PoRAM) device, a Magnetic Random Access Memory (MRAM), a Ferroelectric Random Access Memory (FRAM) device, and the like, and/or a volatile memory device such as a Dynamic Random Access Memory (DRAM) device, a Static Random Access Memory (SRAM) device, mobile DRAM device, or the like.

The storage device SD may include at least one of a Solid State Drive (SSD), a Hard Disk Drive (HDD), a CD-ROM, and the like.

The input/output device IO may include input means such as a keyboard, keypad, touchpad, touchscreen, mouse, and the like, and output means such as a speaker, a printer, and the like. According to an embodiment, the display device 1000 may be included in the input/output device IO.

The power supply PS may supply power required for operation of the electronic device ED. For example, the power supply PS may include a power management integrated circuit (PMIC).

The display device 1000 may display an image corresponding to visual information of the electronic device ED. The display device 1000 may be an organic light emitting display device or a quantum dot light emitting display device, but the disclosure is not limited thereto. The display device 1000 may be connected to other components through buses or other communication links. The display device DD of FIG. 1 may be provided as the display device 1000.

Referring to FIG. 16, a smartphone 2000 including the display device according to embodiments of the disclosure may have improved driving reliability.

Referring to FIG. 17, a tablet PC 3000 including the display device according to embodiments of the disclosure may have improved driving reliability.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first buffer layer disposed on a substrate;
a first active layer disposed on the first buffer layer;
a first interlayer insulating layer disposed on the first buffer layer and the first active layer;
a first interlayer conductive layer disposed on the first interlayer insulating layer;
a second interlayer insulating layer disposed on the first interlayer conductive layer;
a second buffer layer disposed on the second interlayer insulating layer; and
a second active layer disposed on the second buffer layer, wherein the first interlayer insulating layer includes a first contact hole exposing the first active layer in a thickness direction, and
in a plan view, the first contact hole does not overlap the second active layer.

2. The display device of claim 1, wherein, in the plan view, the second active layer includes active patterns arranged with a gap in a first direction and extending in a second direction intersecting the first direction.

3. The display device of claim 2, wherein a diameter of the first contact hole in the plan view is smaller than the gap between the active patterns of the second active layer.

4. The display device of claim 2, further comprising:
a second gate layer disposed on the second active layer and extending in the first direction.

5. The display device of claim 4, wherein the first contact hole does not overlap the second gate layer in the plan view.

6. The display device of claim 5, wherein the first contact hole is arranged adjacent to the second active layer in the first direction and adjacent to the second gate layer in the second direction.

7. The display device of claim 1, further comprising:
a first gate layer disposed between the first interlayer insulating layer and the first active layer,
wherein the first contact hole exposes the first gate layer in the thickness direction.

8. The display device of claim 4, further comprising:
a third interlayer insulating layer disposed on the second active layer, the second gate layer, and the second buffer layer,
wherein the third interlayer insulating layer includes a third contact hole overlapping the second active layer in the plan view.

9. The display device of claim 8, wherein, in the plan view, the third contact hole does not overlap the first contact hole.

10. The display device of claim 9, wherein the third contact hole exposes the second active layer in the thickness direction.

11. The display device of claim 8, further comprising:
a second interlayer conductive layer disposed on the third interlayer insulating layer,
wherein the second interlayer conductive layer contacts the second active layer through the third contact hole.

12. The display device of claim 11, wherein, in the plan view, the second interlayer conductive layer overlaps the first contact hole.

13. The display device of claim 11, further comprising:
a display area including one or more pixels;
a non-display area located adjacent to the display area; and
a gate driver that transmits a gate signal to the one or more pixel and is disposed in the non-display area.

14. The display device of claim 13, wherein the gate driver includes a buffer transistor including the second active layer, the second gate layer, and the second interlayer conductive layer in the non-display area.

15. The display device of claim 14, wherein the second interlayer conductive layer overlapping the third contact hole in the plan view is included in a channel region of the buffer transistor.

16. An electronic device comprising:
a processor; and
a display device including pixels, the display device displaying an image under control of the processor, wherein
the display device further includes:
a first buffer layer disposed on a substrate;
a first active layer disposed on the first buffer layer;
a first interlayer insulating layer disposed on the first buffer layer and the first active layer;
a first interlayer conductive layer disposed on the first interlayer insulating layer;
a second interlayer insulating layer disposed on the first interlayer conductive layer;
a second buffer layer disposed on the second interlayer insulating layer; and
a second active layer disposed on the second buffer layer,
the first interlayer insulating layer includes a first contact hole exposing the first active layer in a thickness direction, and
in a plan view, the first contact hole does not overlap the second active layer.

17. The electronic device of claim 16, wherein,
in the plan view, the second active layer includes active patterns arranged with an interval in a first direction and extending in a second direction intersecting the first direction, and
a diameter of the first contact hole in the plan view is smaller than the interval between the active patterns of the second active layer.

18. The electronic device of claim 17, further comprising:
a second gate layer disposed on the second active layer and extending in the first direction,
wherein the first contact hole does not overlap the second gate layer in the plan view.

19. The electronic device of claim 18, further comprising:
a third interlayer insulating layer disposed on the second active layer, the second gate layer, and the second buffer layer,
wherein the third interlayer insulating layer includes a third contact hole overlapping the second active layer in the plan view.

20. The electronic device of claim 19, wherein, in the plan view, the third contact hole does not overlap the first contact hole.
